(19) United States
(12) Patent Application Publication
(10) Pub. No.: US 2017/0278851 A1
(43) Pub. Date: Sep. 28, 2017

(54) SEMICONDUCTOR MEMORY DEVICE

(71) Applicant: Kabushiki Kaisha Toshiba, Minato-ku (JP)

(72) Inventors: Kotaro FUJII, Yokkaichi (JP); Hideaki Aochi, Yokkaichi (JP); Yasuhito Yoshimizu, Yokkaichi (JP)

(73) Assignee: Kabushiki Kaisha Toshiba, Minato-ku (JP)

(21) Appl. No.: 15/237,849

(22) Filed: Aug. 16, 2016

Related U.S. Application Data
(60) Provisional application No. 62/312,173, filed on Mar. 23, 2016.

(51) Int. Cl. H01L 27/115; H01L 21/28

(52) U.S. Cl. CPC H01L 27/1157; H01L 27/11582; H01L 21/28282

(57) ABSTRACT

A semiconductor memory device according to one embodiment includes a stacked body and a semiconductor layer. The stacked body includes a plurality of control gate electrodes stacked above a substrate. The semiconductor layer extends in a first direction intersecting with the substrate and faces the plurality of control gate electrodes. The semiconductor memory device further includes a gate insulating layer disposed between the control gate electrodes and the semiconductor layer. The gate insulating layer includes zirconium oxide at a position facing the control gate electrodes.

### CROSS REFERENCE TO RELATED APPLICATIONS

This application is based on and claims the benefit of priority from prior U.S. Provisional Patent Application No. 62/312,173, filed on Mar. 23, 2016, the entire contents of which are incorporated herein by reference.

### FIELD

Embodiments described herein relate to a semiconductor memory device.

### BACKGROUND

### Description of the Related Art

A flash memory that stores data by accumulating a charge in a charge accumulation layer is known. Such a flash memory is connected by a variety of systems such as NAND type or NOR type, and configures a semiconductor memory device. In recent years, in order to accomplish increasing of capacitance and raising of integration level of such a nonvolatile semiconductor memory device, a semiconductor memory device in which memory cells are arranged three-dimensionally (three-dimensional type semiconductor memory device) has been proposed.

### BRIEF DESCRIPTION OF THE DRAWINGS

FIG. 1 is a block diagram of a nonvolatile semiconductor memory device according to a first embodiment.

FIG. 2 is a circuit diagram showing a configuration of part of the nonvolatile semiconductor memory device.

FIG. 3 is a perspective view showing a configuration of part of the nonvolatile semiconductor memory device.

FIG. 4 is a perspective view showing a configuration of part of the nonvolatile semiconductor memory device.

FIG. 5 is a plan view showing a configuration of part of the nonvolatile semiconductor memory device.

FIG. 6 is a cross-sectional view showing a configuration of part of the nonvolatile semiconductor memory device.

FIG. 7 is a cross-sectional view showing a configuration of part of the nonvolatile semiconductor memory device.

FIG. 8 is a cross-sectional view showing a configuration of part of the nonvolatile semiconductor memory device.

FIG. 9 is a flow chart that describes a method of manufacturing the nonvolatile semiconductor memory device.

FIGS. 10 to 18 are cross-sectional views that describe the method of manufacturing.

FIG. 19 is a plan view that supplementarily describes the method of manufacturing.

FIG. 20 is a cross-sectional view that supplementarily describes the method of manufacturing.

FIG. 21 is a cross-sectional view showing a configuration of part of a nonvolatile semiconductor memory device according to a second embodiment.

FIGS. 22 and 23 are cross-sectional views that describe a method of manufacturing the nonvolatile semiconductor memory device.

FIG. 24 is a cross-sectional view showing a configuration of part of a nonvolatile semiconductor memory device according to a third embodiment.

FIG. 25 is a plan view showing a configuration of part of a nonvolatile semiconductor memory device according to a fourth embodiment.

FIGS. 26 to 28 are cross-sectional views that describe a method of manufacturing a nonvolatile semiconductor memory device according to comparative example.

### DETAILED DESCRIPTION

A semiconductor memory device according to one embodiment includes a stacked body and a semiconductor layer. The stacked body includes a plurality of control gate electrodes stacked above a substrate. The semiconductor layer extends in a first direction intersecting with the substrate and faces the plurality of control gate electrodes.

The semiconductor memory device includes a gate insulating layer disposed between the control gate electrodes and the semiconductor layer. The gate insulating layer includes zirconium oxide at a position facing the control gate electrodes.

Next, a nonvolatile semiconductor memory device according to embodiments will be described in detail with reference to drawings. Note that these embodiments are merely examples, and are not shown with the intention of limiting the present invention.

For example, a non-volatile semiconductor memory device described below has a structure in which a memory string extends in a straight line in a direction intersecting with the substrate. A similar structure is also applicable to the structure having a U shaped memory string that is folded to the opposite side in the middle. Moreover, each of the drawings of the nonvolatile semiconductor memory devices employed in the embodiments below is schematic, and thicknesses, widths, ratios, and so on, of layers are different from those of the actual nonvolatile semiconductor memory devices.

The nonvolatile semiconductor memory devices described below relates to a nonvolatile semiconductor memory device having a structure in which a plurality of MONOS (Metal-Oxide-Nitride-Oxide-Semiconductor) type memory cells (memory transistors) are provided in a height direction, each of the MONOS type memory cells including a semiconductor layer as a channel body and a control gate electrode made of metal and provided on a side surface of the semiconductor layer via a charge accumulation layer. However, this is also not intended to limit the present invention, and the present invention may be applied also to a structure having another form of the charge accumulation layer, for example, a SONOS (Semiconductor-Oxide-Nitride-Oxide-Semiconductor) type memory cell having control gate electrodes made of semiconductor, or a structure having a floating gate type memory cell.

With regard to an example of the structure having floating gate-type memory cell, reference is made to the U.S. patent application Ser. No. 13/112,345 whose disclosure content is herewith incorporated by this reference.

### First Embodiment

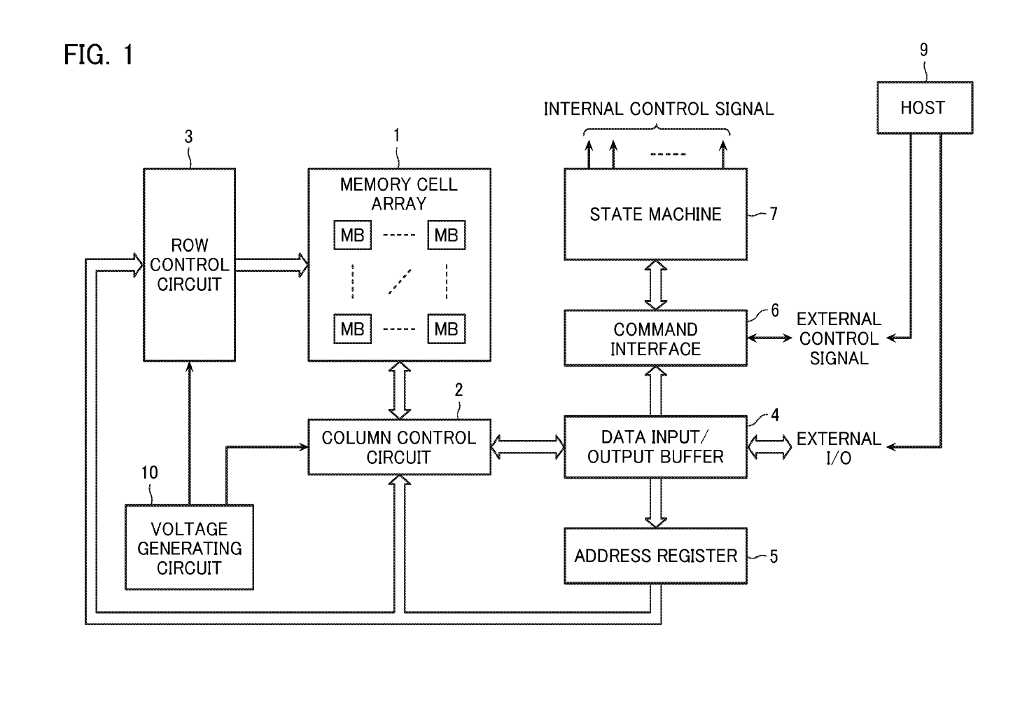

FIG. 1 is a block diagram of a nonvolatile semiconductor memory device according to a first embodiment. The nonvolatile semiconductor memory device stores user data inputted from an external host 9 in a memory cell array 1. In addition, the nonvolatile semiconductor memory device reads the user data from the memory cell array 1 and outputs the user data to the external host 9. The memory cell array 1 includes a plurality of memory blocks MB. These memory blocks MB each record the user data. The memory block MB is a minimum unit of an erase operation. Moreover, the nonvolatile semiconductor memory device includes a column control circuit 2. The column control circuit 2 includes an unillustrated sense amplifier and performs reading the user data and the like. When the user data is written, the column control circuit 2 transfers voltage generated by a voltage generating circuit 10 to the memory cell array 1 according to inputted user data.

The nonvolatile semiconductor memory device includes a row control circuit 3. The row control circuit 3 assigns a position for performing reading or writing of the user data in the memory cell array 1 according to inputted address data.

The nonvolatile semiconductor memory device includes an address register 5, the voltage generating circuit 10, a state machine 7, a data input/output buffer 4, and the like. The address register 5 stores the address data and provides the address data to the column control circuit 2 and the row control circuit 3. The voltage generating circuit 10 generates a voltage and provides the voltage to the column control circuit 2 and the row control circuit 3. The state machine 7 receives an external control signal from the host 9 via a command interface 6 and inputs an internal control signal to the voltage generating circuit 10 and the like. The data input/output buffer 4 performs input/output control of the user data, the address data and command data.

Note that, the column control circuit 2, the row control circuit 3, the state machine 7, the voltage generating circuit 10, and the like configure a control circuit that controls the memory cell array 1. Moreover, a specific configuration can be properly changed.

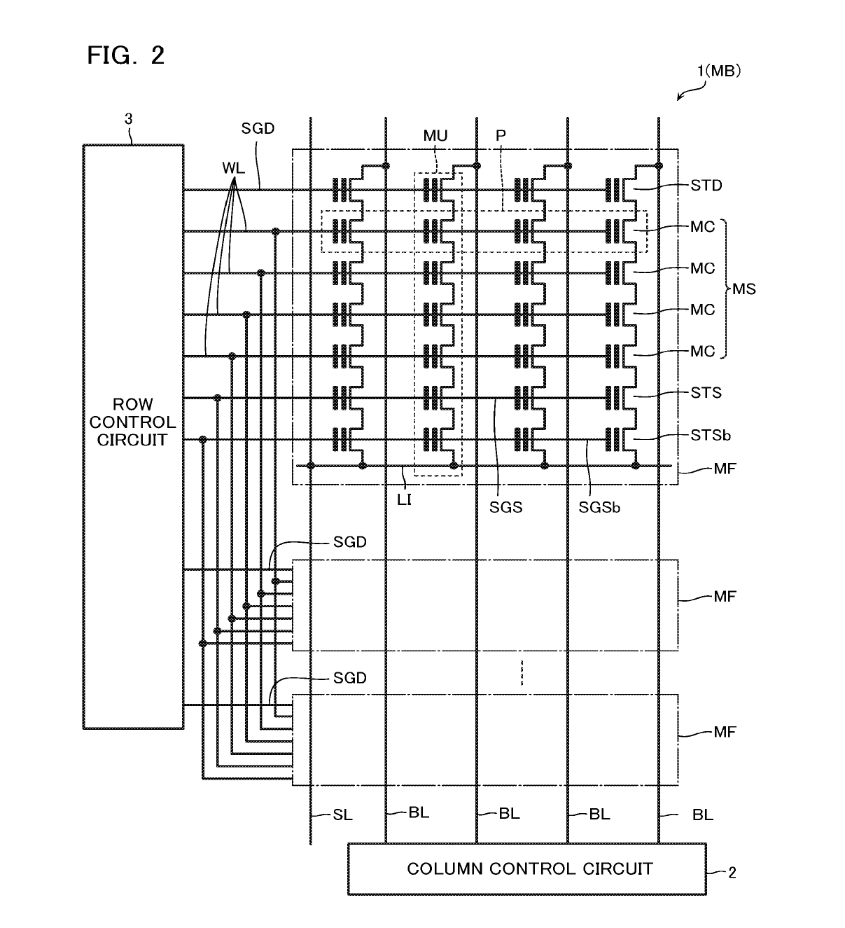

FIG. 2 is an equivalent circuit diagram showing a configuration of the memory block MB configuring the memory cell array 1.

The memory block MB includes a plurality of memory fingers MF. The memory finger MF includes a plurality of pages P. The page P is a memory region included in a plurality of memory cells MC connected to one word line WL. The pages P each store the user data read in a lump, in a reading operation. The memory cells MC each store data of one bit or a plurality of bits that configures the user data.

When performing the reading operation, the row control circuit 3 selects a certain drain side select gate line SGD according to the address data. Hereby, a certain memory finger MF is selected. Moreover, the row control circuit 3 selects a certain word line WL according to the address data. Hereby, a certain page P is selected. The plurality of memory cells MC included in the selected page P each are connected to the column control circuit 2 via bit lines BL. The column control circuit 2 reads data stored in the memory cell MC based on a current or a voltage of the bit line BL. The column control circuit 2 outputs the read data as the user data.

Next, with continuously reference to FIG.2, a circuit configuration of the memory cell array 1 will be described in further detail. The memory blocks MB each include the plurality of memory fingers MF. The memory finger MF includes a plurality of memory units MU. The plurality of memory units MU each are connected to the plurality of bit lines BL at one ends. Moreover, the plurality of memory units MU each are connected to a common source contact LI at other ends and connected to a source line SL via the source contact LI. The memory unit MU has a drain side select gate transistor STD, a memory string MS, a source side select gate transistor STS and a lowermost layer source side select gate transistor STSb. The drain side select gate transistor STD is connected to the bit line BL. The memory string MS is connected to the drain side select gate transistor STD. The source side select gate transistor STS is connected in series between the memory string MS and the source contact LI.

The memory string MS includes the plurality of memory cells MC connected in series. The memory cell MC is a field effect type transistor including a semiconductor layer that functions as a channel body, a gate insulating layer that can accumulate a charge, and a control gate electrode. The memory cell MC accumulates a charge in the gate insulating layer according to a voltage applied to the control gate electrode. Subsequently, the memory cell MC forms a channel (an inversion layer) in the semiconductor layer and changes a control gate voltage (a threshold voltage) to make the semiconductor layer in a conductive state. Note that, a common word line WL is connected to the control gate electrodes of the plurality of memory cells MC included in a same page P.

The drain side select gate transistor STD, the source side select gate transistor STS and the lowermost layer source side select gate transistor STSb are field effect type transistors that have control gate electrodes and semiconductor layers that function as channel bodies. Moreover, the control gate electrodes of the drain side select gate transistor STD, the source side select gate transistor STS and the lowermost layer source side select gate transistor STSb are connected to a drain side select gate line SGD, a source side select gate line SGS and a lowermost layer source side select gate line SGSb, respectively.

Note that, in the following description, the lowermost layer source side select gate transistor STSb, the source side select gate transistor STS and the drain side select gate transistor STD may be merely called as select gate transistors (STSb, STS and STD). In addition, in the following description, the lowermost layer source side select gate line SGSb, the source side select gate line SGS and the drain side select gate line SGD maybe merely called as select gate lines (SGSb, SGS and SGD).

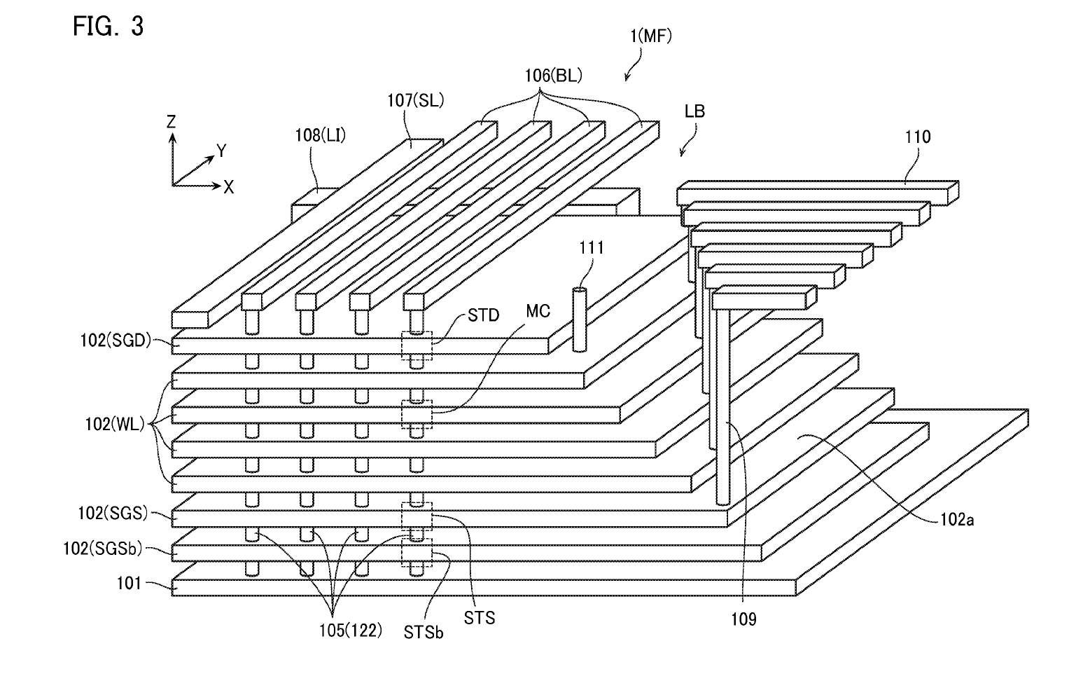

Next, a schematic structure of the memory cell array 1 will be described. FIG.3 is a schematic perspective view showing a configuration of part of the memory finger MF, and part of the configuration is omitted. Note that, FIG. 3 is illustrated for description; a specific structure may be properly changed.

The memory finger MF includes a substrate 101 and a laminated body LB. The laminated body LB includes a plurality of conductive layers 102 laminated above the substrate 101. The conductive layers 102 function as the word lines WL and the control gate electrodes of the memory cells MC and the like. The memory finger MF extends in a Z direction intersecting with an upper surface of the substrate 101 and includes a plurality of memory columnar bodies 105 that configure the memory string MS and the like with the laminated body LB.

The laminated body LB includes the plurality of conductive layers 102 laminated above the substrate 101. These conductive layers 102 are formed of conductive layers such as tungsten (W), for example. These conductive layers 102 each function as the word lines WL, the control gate electrodes of the memory cells MC, the select gate lines (SGSb, SGS and SGD) or the control gate electrodes of the select gate transistors (STSb, STS and STD). Moreover, the conductive layers 102 each have a contact portion 102a protruding in an X direction compared with the conductive layer 102 positioned at an upper layer thereof. The conductive layers 102 each are connected to the row control circuit 3 (FIGS. 1 and 2) via a via contact wiring 109 connected to a surface of the contact portion 102a, and via a wiring 110. Note that, the via contact wiring 109 and the wiring 110 are formed of conductive layers such as tungsten (w).

The memory columnar body 105 has a columnar shape extending in a first direction (the Z direction) perpendicular to the substrate 101, and configures the memory string MS and the like with the laminated body LB. That is, intersections of the memory columnar body 105 and the plurality of conductive layers as the control gate electrodes laminated above the substrate 101 function as the memory cells MC or the select gate transistors (STSb, STS and STD). The memory columnar body 105 includes a semiconductor layer 122 extending in the first direction (the Z direction) perpendicular to the substrate 101. The semiconductor layer 122 faces the plurality of conductive layers 102 acting as the control gate electrodes in the laminated body LB, and functions as channel bodies of the memory cells MC and the select gate transistors (STSb, STS and STD). A lower end of the semiconductor layer 122 is connected to an unillustrated source line driver via the substrate 101, a conductive layer 108 and a conductive layer 107. The conductive layer 108 is disposed above the substrate 101 and functions as the source contact LI. The conductive layer 107 is disposed above the conductive layer 108 and functions as the source line SL. An upper end of the semiconductor layer 122 is connected to the column control circuit 2 (FIGS. 1 and 2) via a conductive layer 106 that functions as the bit line BL. Note that, the conductive layer 106, the conductive layer 107 and the conductive layer 108 are formed of conductive layers such as tungsten (W). A plurality of the conductive layers 106 and the conductive layer 107 are disposed in the X direction parallel to the substrate 101, and extend in a Y direction that is parallel to the substrate 101 and intersects with the X direction.

In addition, as shown in the middle of FIG. 3, the memory finger MF includes a dummy structure 111. The dummy structure 111 has a columnar shape extending in the Z direction like the memory columnar body 105. In a process of manufacturing, the dummy structure 111 acts as a support structure that makes an unillustrated insulating layer and the like disposed between the conductive layers 102 maintain their postures. Note that, the dummy structure 111 may have a similar structure to the memory columnar body 105, and may be formed of an insulating layer such as silicon oxide (SiO₂), for example.

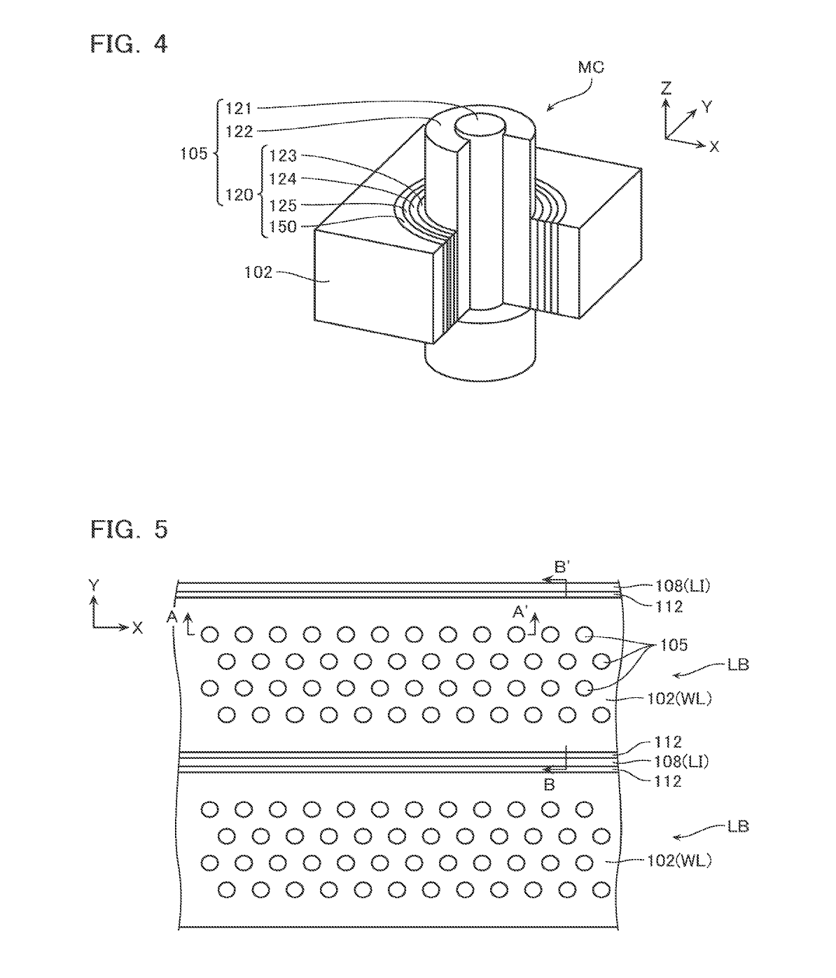

Next, a schematic configuration of the memory cell MC will be described. FIG. 4 is a schematic perspective view showing a configuration of the memory cell MC. Although not illustrated in FIG. 4, the select gate transistors (STSb, STS and STD) may also have a similar configuration to the memory cell MC.

The memory cell MC is disposed at an intersection of the conductive layer 102 and the memory columnar body 105. The memory columnar body 105 extends in the Z direction. The memory columnar body 105 includes a columnar core insulating layer 121, the semiconductor layer 122 covering a side surface of the core insulating layer 121 and a gate insulating layer 120 disposed between the conductive layer 102 and the semiconductor layer 122. The gate insulating layer 120 includes a tunnel insulating layer 123, a charge accumulation layer 124, a first block insulating layer 125 and a second block insulating layer 150. The tunnel insulating layer 123 covers a side surface of the semiconductor layer 122. The charge accumulation layer 124 covers a side surface of the tunnel insulating layer 123. The first block insulating layer 125 covers a side surface of the charge accumulation layer 124. The second block insulating layer 150 covers a side surface of the first block insulating layer 125. The second block insulating layer 150 is disposed between the first block insulating layer 125 and the conductive layer 102 and includes zirconium oxide (ZrO₂). A layer including zirconium-aluminum oxide (ZrAlO) instead of zirconium oxide (ZrO₂) may be used as the second block insulating layer 150.

The core insulating layer 121 is formed of an insulating layer such as silicon oxide (SiO₂), for example. The semiconductor layer 122 is formed of a semiconductor layer such as polysilicon, for example, and has a cylindrical shape extending in the Z direction along a side surface of the core insulating layer 121. Note that, the semiconductor layer 122 may have a columnar shape, for example. The semiconductor layer 122 functions as the channel body of the memory cells MC and the select gate transistors (STSb, STS and STD). The tunnel insulating layer 123 is formed of an insulating layer such as silicon oxide (SiO₂), for example. The charge accumulation layer 124 is formed of an insulating layer that can accumulate a charge, such as silicon nitride (Si₃N₄), for example. The first block insulating layer 125 is configured by an insulating layer such as silicon oxide (SiO₂), for example, as a material. Note that, the first block insulating layer 125 is not necessarily formed of only silicon oxide, and may be a laminated structure of silicon oxide and another insulating material. The semiconductor layer 122 and the gate insulating layer 120 have cylindrical shapes extending in the Z direction along the side surface of the core insulating layer 121.

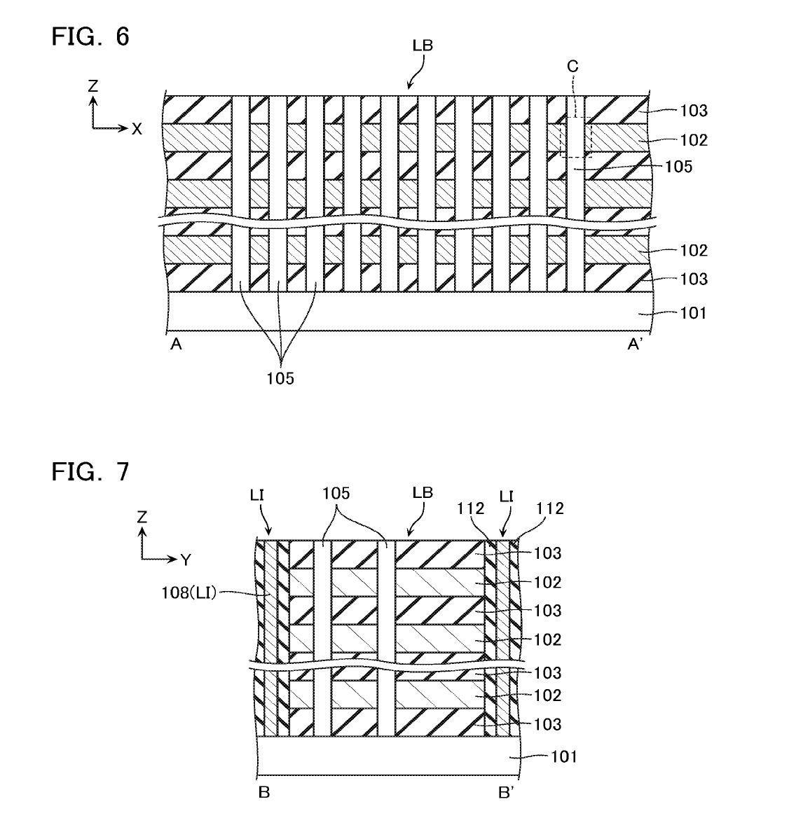

FIG. 5 is a plan view showing a configuration of part of the nonvolatile semiconductor memory device. The nonvolatile semiconductor memory device includes the laminated body LB and a plurality of the memory columnar bodies 105. The laminated body LB includes the conductive layers 102 that function as the word lines WL and the like, and inter layer insulating layers 103 (not illustrated in FIG. 5). The plurality of the memory columnar bodies 105 whose side surfaces are covered by the laminated body LB. The plurality of the memory columnar bodies 105 configure the memory strings MS and the like (not illustrated in FIG. 5) with the laminated body LB. The memory columnar bodies 105 are disposed so as to be staggered at a certain density in an X-Y plane. Note that, arrangement of the memory columnar bodies 105 is not limited to staggered arrangement, and may be properly changed to triangular arrangement, quadrilateral arrangement, and the like.

A plurality of the laminated bodies LB extend in the X direction and are arranged in the Y direction. The laminated bodies LB include the conductive layer 108 that functions as the source contact LI and that is disposed between the conductive layers 102 adjacent in the Y direction via insulating layers 112. The conductive layers 102 and the conductive layer 108 are formed of conductive layers such as tungsten (W), for example. The interlayer insulating layers 103 (not illustrated) and the insulating layers 112 are formed of insulating layers such as silicon oxide (SiO₂), for example.

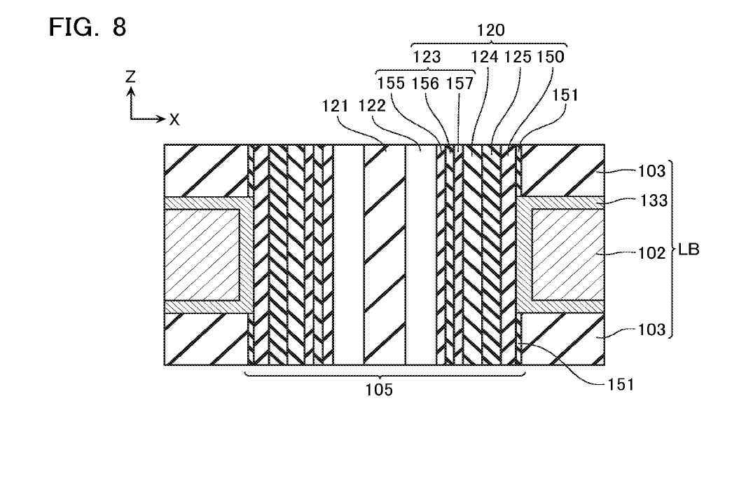

FIG. 6 is a cross-sectional view of part corresponding to A-A′ line of FIG. 5, and shows a configuration of part of the nonvolatile semiconductor memory device. The memory columnar bodies 105 penetrate the laminated body LB configured by the conductive layers 102 and the interlayer insulating layers 103, and in lower portions thereof are connected to the substrate 101. Portions that the memory columnar bodies 105 that connect to the conductive layers 102 each have internal structures shown in FIG. 4, and configure the memory unit MU (described above) extending in the Z direction.

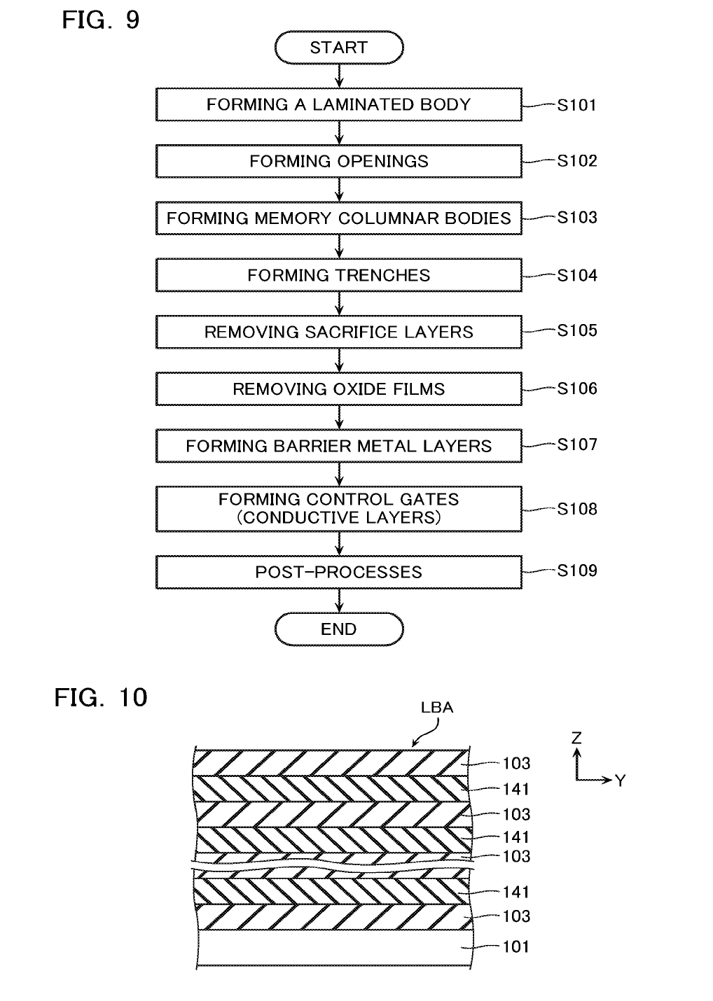

FIG. 7 is a cross-sectional view of part corresponding to B-B′ line of FIG. 5. In addition to the memory columnar bodies 105, the conductive layer 108 (source contact LI) sandwiched by the insulating layers 112 is shown in FIG. 7.

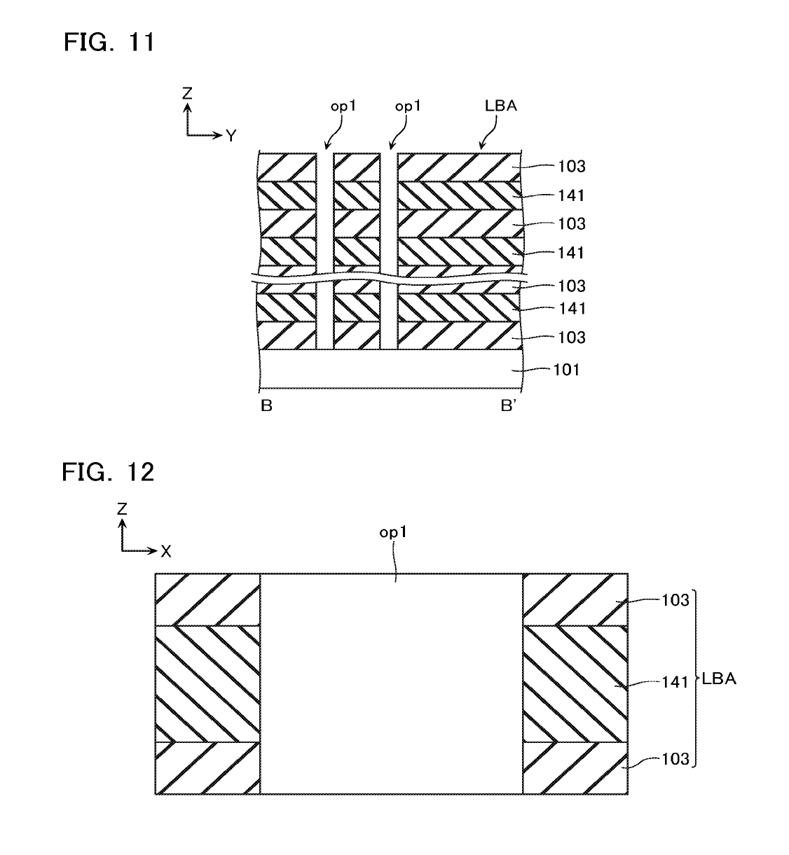

FIG. 8 is a cross-sectional view showing a configuration of part of the nonvolatile semiconductor memory device in further detail, and is an enlarged view of a portion of dotted rectangle C shown in FIG. 6.

A configuration of the memory columnar body 105 will be described from the center part to outside in order. The core insulating layer 121 including silicon oxide (SiO₂), for example, is disposed at the center part of the memory columnar body 105. The semiconductor layer 122 is disposed on a side surface of the core insulating layer 121. The semiconductor layer 122 is formed of a semiconductor layer such as polysilicon, for example, and functions as the channel body of the memory cells MC and the like.

The tunnel insulating layer 123 is disposed outside of the semiconductor layer 122. The tunnel insulating layer 123 is configured by an oxide layer 155 including silicon oxide (SiO₂), for example, a nitride layer 156 including silicon nitride (Si₃N₄), for example, and a oxide layer 157 including silicon oxide (SiO₂), for example.

The charge accumulation layer 124 formed of an insulating layer that can accumulate a charge, such as silicon nitride (Si₃N₄), for example, is disposed outside of the tunnel insulating layer 123. Furthermore, the first block insulating layer 125 is disposed outside of the charge accumulation layer 124. The first block insulating layer 125 is formed of an insulating layer including silicon oxide (SiO₂), for example.

Moreover, the second block insulating layer 150 including zirconium oxide (ZrO₂) is disposed outside of the first block insulating layer 125. A barrier metal layer 133 is disposed between the second block insulating layer 150 and the conductive layer 102. That is, the second block insulating layer 150 configures part of the gate insulating layer 120 and is positioned at a side closer to the conductive layer 102 in the gate insulating layer 120. The second block insulating layer 150 is disposed at a position facing the conductive layer 102 via the barrier metal layer 133. The conductive layers 102 covered by the barrier metal layers 133 are electrically isolated by the interlayer insulating layers 103 in a laminating direction (the Z direction).

A protective layer 151 including silicon oxide (SiO₂) is disposed between the interlayer insulating layer 103 and the second block insulating layer 150. Hence, the protective layer 151 is disposed at a side closer to the control gate electrode (the conductive layer 102) than the second block insulating layer 150. However, the protective layer 151 is not disposed at a region that the conductive layer 102 faces the second block insulating layer 150 including zirconium oxide (ZrO₂) via the barrier metal layer 133. That is because the protective layer 151 in this region is removed by etching in a manufacturing process described in detail below.

The protective layer 151 including silicon oxide (SiO₂) protects the second block insulating layer 150 in the manufacturing process.

The layers from the core insulating layer 121 to the second block insulating layer 150 and the protective layer 151 configure the memory columnar body 105. A periphery of the memory columnar body 105 is surrounded by the conductive layers 102 and the interlayer insulating layers 103.

The conductive layers 102 function as the word lines WL or the select gate lines (SGSb, SGS and SGD). The conductive layers 102 are connected to the memory columnar body 105 via the barrier metal layers 133 for preventing diffusion of impurities in metal.

The conductive layers 102 are formed of conductive layers such as tungsten (W), for example. The barrier metal layers 133 are formed of metal including at least one of titanium nitride (TiN), titanium silicon nitride (TiSiN), tantalum nitride (TaN), tantalum-silicon nitride (TaSiN) and tungsten nitride (WN), for example. The interlayer insulating layers 103 are formed of insulating layers such as silicon oxide (SiO₂), for example.

In this embodiment, the second block insulating layer 150 including zirconium oxide (ZrO₂) has protective function in the manufacturing process. Furthermore, the second block insulating layer 150 including zirconium oxide (ZrO₂) has an effect of reducing malfunctions in the erase operation of the memory cell MC, because the second block insulating layer 150 has high permittivity.

### [Method of Manufacturing]

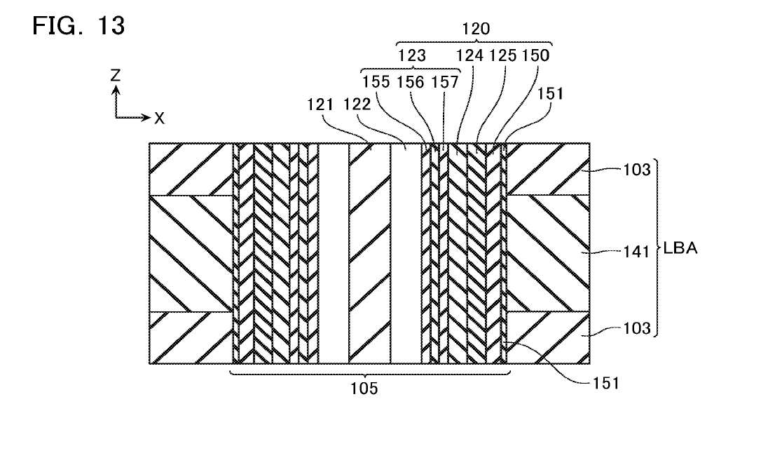

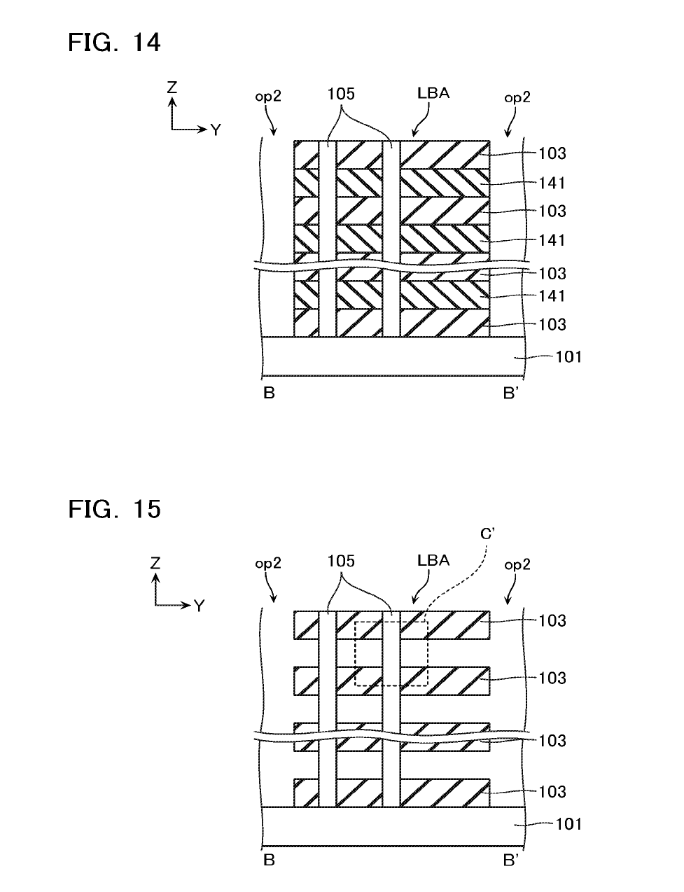

Next, with reference to FIGS. 9 to 18, a method of manufacturing the nonvolatile semiconductor memory device according to the first embodiment will be described. FIG. 9 is a flow chart that describes the method of manufacturing. FIGS. 10 to 18 are cross-sectional views that describe the method of manufacturing the nonvolatile semiconductor memory device and illustrate cross sections corresponding to parts shown in FIGS. 7 and 8, respectively.

Hereinafter, each of the steps shown in FIG. 9 will be described in order. In a step S101, “forming a laminated body”, as shown in FIG. 10, a laminated body LBA (a second laminated body) including the plurality of the interlayer insulating layers 103 and sacrifice layers 141 are formed above the substrate 101. The interlayer insulating layers 103 are formed by depositing insulating layers such as silicon oxide (SiO₂) by a method such as CVD (Chemical Vapor Deposition), for example. The sacrifice layers 141 are formed by depositing silicon nitride (Si₃N₄), for example, by a method such as CVD.

In a step S102, “forming openings”, as shown in FIG. 11, openings op1 are formed so as to penetrate the laminated body LBA configured by the plurality of interlayer insulating layers 103 and the sacrifice layers 141 and to expose an upper surface of the substrate 101. The openings op1 are openings to form the memory columnar bodies 105, and have longitudinally the first direction (the Z direction). The openings op1 are formed by a method such as RIE (Reactive Ion Etching), for example.

FIG. 12 is a cross-sectional view showing an enlarged part of FIG. 11, and corresponds to a portion of the dotted rectangle C shown in FIG. 6. In a step S103, “forming memory columnar bodies”, each layer that configures the memory columnar body 105 is formed in the following order by a method such as CVD on a side surface of the opening op1 of FIG. 12, so as to obtain a configuration shown in FIG. 13.

First, silicon oxide (SiO₂) as the protective layer 151 is formed on the side surface of the opening op1. Next, the second block insulating layer 150 including zirconium oxide (ZrO₂) is formed on a side surface of the protective layer 151. Subsequently, silicon oxide (SiO₂) as a material of the first block insulating layer 125 is formed on a side surface of the second block insulating layer 150.

Next, the charge accumulation layer 124 formed of silicon nitride (Si₃N₄), for example, is formed on a side surface of the first block insulating layer 125. Next, the oxide layer 157 formed of silicon oxide (SiO₂), the nitride layer 156 formed of silicon nitride (Si₃N₄) and the oxide layer 155 formed of silicon oxide (SiO₂), for example, as the tunnel insulating layer 123 are formed in this order on a side surface of the charge accumulation layer 124.

Next, polysilicon as a material of the semiconductor layer 122 is formed on a side surface of the oxide layer 155. Next, silicon oxide (SiO₂) as a material of the core insulating layer 121 is formed on a side surface of the semiconductor layer 122. In this embodiment, the opening op1 is embedded as a result of forming each layer.

As shown in FIG. 14, in a step S104, “forming trenches”, openings op2 (trenches) are formed in the laminated body LBA. The openings op2 are trenches extending in the X direction, dividing the plurality of interlayer insulating layers 103 and the sacrifice layers 141 in the Y direction, and exposing an upper surface of the substrate 101. The openings op2 are formed by a method such as RIE, for example.

In a step S105, “removing sacrifice layers”, the sacrifice layers 141 are removed by performing wet etching and the like using hot phosphoric acid via the openings op2 as shown in FIG. 15. As a result of removing the sacrifice layers 141, the plurality of interlayer insulating layers 103 and the memory columnar bodies 105 remain above the substrate 101.

FIG. 16 is a cross-sectional view showing an enlarged portion of a dotted rectangle C′ shown in FIG. 15. The hot phosphoric acid does not contact the second block insulating layer 150 including zirconium oxide (ZrO₂) because the protective layer 151 using thin silicon oxide (SiO₂) exists. Hence, a film thickness of the second block insulating layer 150 including zirconium oxide (ZrO₂) does not decrease.

In a step S106, “removing oxide films”, the protective layer 151 using thin silicon oxide (SiO₂) described above is removed by dilute hydrofluoric acid so as to obtain a state shown in FIG. 17.

In a step S107, “forming barrier metal layers”, the barrier metal layer 133 is formed as shown in FIG. 18. The barrier metal layer 133 is formed of metal including at least one of titanium nitride (TiN), titanium silicon nitride (TiSiN), tantalum nitride (TaN), tantalum silicon nitride (TaSiN), and tungsten nitride (WN), for example, as a material. The barrier metal layer 133 restrains diffusion of impurities such as fluorine included in the conductive layers 102 formed in the next process.

In a step S108, “forming control gates (conductive layers)”, the conductive layers 102 that function as control gate electrodes of the memory cells MC and the like are formed. Tungsten (W) and the like is deposited by a method such as CVD on an upper surface, a lower surface and a side surface of the barrier metal layer 133 via the openings op2 so as to obtain a cross-sectional shape shown in FIG. 8.

Moreover, in a step S109, “post-processes”, post-processes are performed to form the insulating layers 112 and the conductive layer 108 and the like shown in FIG. 5 so as to manufacture the semiconductor memory device according to this embodiment.

Functions of the protective layer 151 including silicon oxide (SiO₂) and the second block insulating layer 150 including zirconium oxide (ZrO₂) in this embodiment will be described.

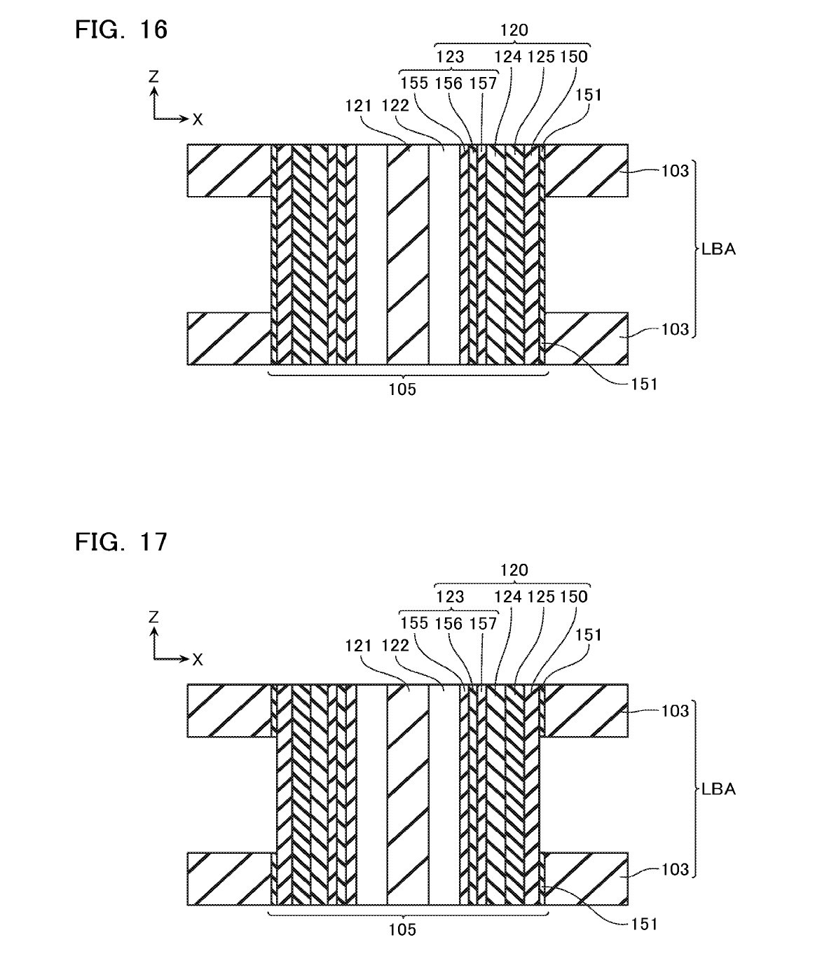

An effect of the protective layer 151 including silicon oxide (SiO₂) will be described with reference to FIG. 19. Although the same drawing as FIG. 5 is used in FIG. 19, the memory columnar bodies 105 arranged in staggered arrangement are divided into four lines, and each line is represented as a line L1, a line L2, a line L3 and a line L4.

Portions in FIG. 19 represented as the conductive layer 108 (LI) and the insulating layers 112 are still in states of trenches as openings op2 in the step S105 that performs etching of the sacrifice layers 141 with hot phosphoric acid. Since hot phosphoric acid is injected via the openings op2, the sacrifice layers 141 (not illustrated in FIG. 19) are etched from sides closer to the openings op2.

The hot phosphoric acid diffuses toward the memory columnar bodies 105 while etching the sacrifice layers 141. As shown in FIG. 19, the line L1 and the line L4 are closer to the openings op2 compared with the line L2 and the line L3. Hence, the memory columnar bodies 105 positioned in the line L1 and the line L4 are exposed to phosphoric acid for a longer time compared with the memory columnar bodies 105 positioned in the line L2 and the line L3.

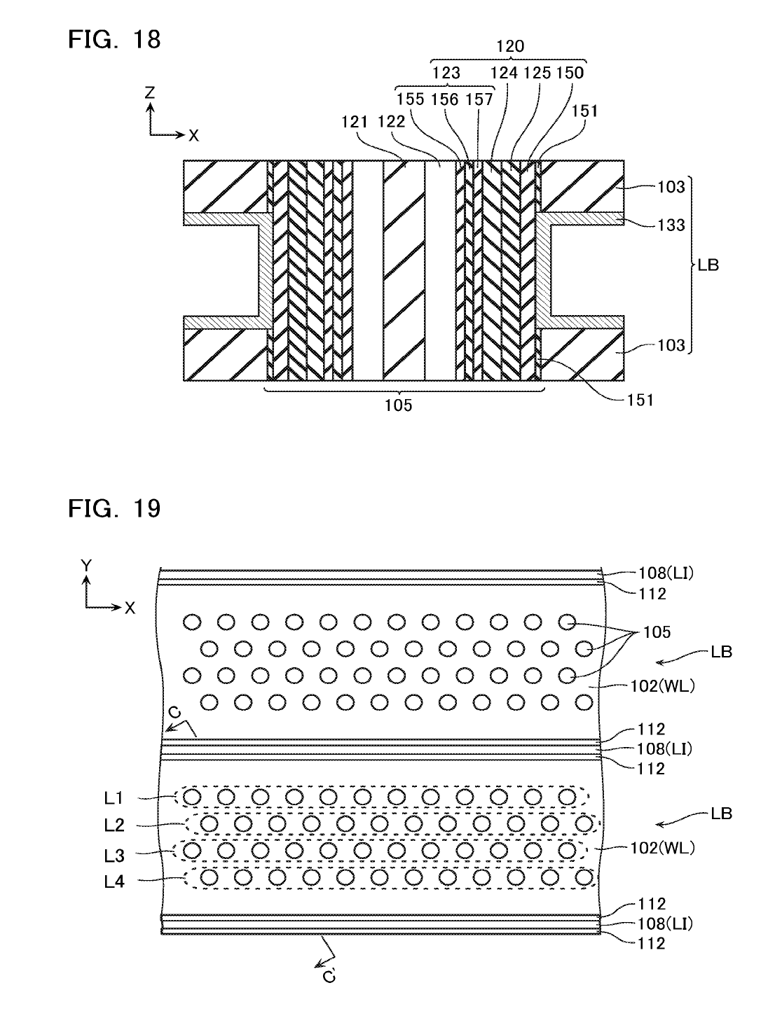

Problems that occur when the protective layer 151 including silicon oxide (SiO₂) is not used will be described with reference to FIG. 20. FIG. 20 shows an oblique cross-section of C-C′ line of FIG. 19. Similar to FIG. 19, portions represented as the conductive layer 108 (LI) and the insulating layers 112 correspond to the openings op2 in the step S105. In FIG. 20, the conductive layers 102 are positioned at positions corresponding to the sacrifice layers 141. When the protective layer 151 including silicon oxide (SiO₂) is not used, the second block insulating layer 150 including zirconium oxide (ZrO₂) and covering the memory columnar body 105 is exposed to hot phosphoric acid in the step 5105. As described above, although etching rate of zirconium oxide (ZrO₂) using the hot phosphoric acid is about 1/60 compared with alumina (AlO₂), there is a difference between times to be exposed to hot phosphoric acid.

In the second block insulating layer 150, only portions facing the conductive layers 102 are exposed to the hot phosphoric acid as shown in FIG. 20. Portions facing the conductive layers 102 in the second block insulating layers 150 included in the memory columnar bodies 105 positioned at the line L1 and the line L4 have a thickness D1. Portions facing the conductive layers 102 in the second block insulating layers 150 included in the memory columnar bodies 105 positioned at the line L2 and the line L3 have a thickness D2. The thickness D1 is slightly thinner than the thickness D2 because of the time difference the second block insulating layers 150 is exposed to hot phosphoric acid.

In contrast, when there are the protective layers 151 including silicon oxide (SiO₂), a thickness of the second block insulating layers 150 does not become thinner. As shown in FIG. 16, the protective layer 151 using thin silicon oxide (SiO₂) prevents the hot phosphoric acid from contacting the second block insulating layer 150 including zirconium oxide (ZrO₂) until etching process of the sacrifice layers 141 by the hot phosphoric acid is finished. Hence, the thicknesses D1 and D2 of the second block insulating layer 150 including zirconium oxide (ZrO₂) are identical regardless of the positions (the line L1, the line L2, the line L3 and the line L4) of the memory columnar bodies 105.

### Second Embodiment

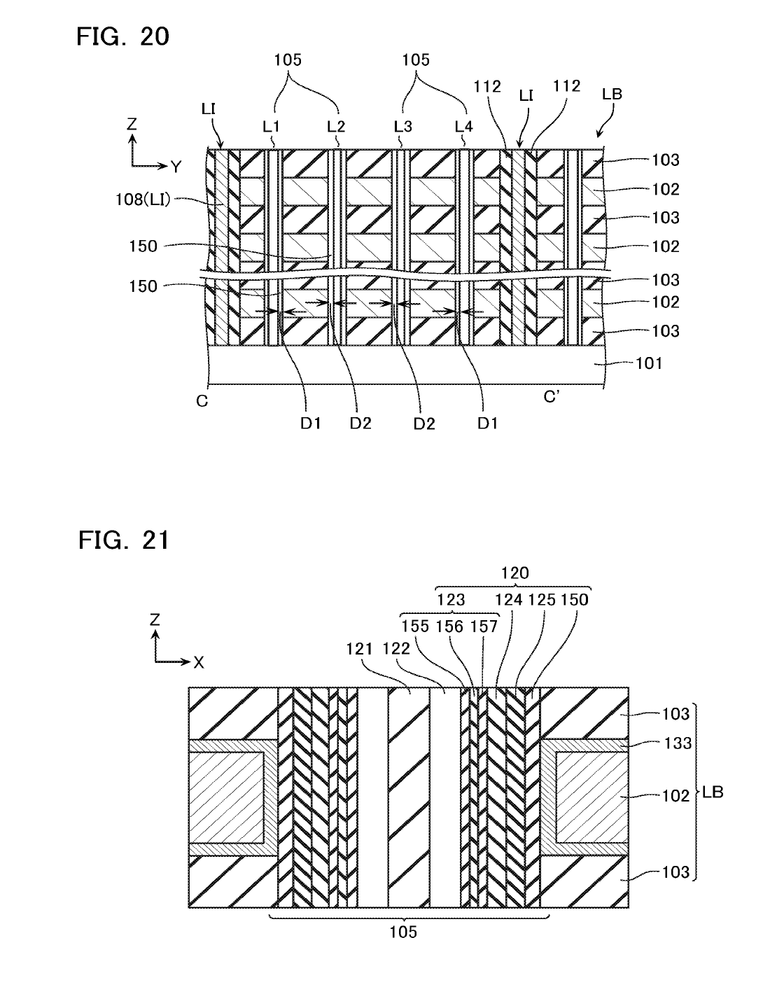

Next, a nonvolatile semiconductor memory device according to a second embodiment will be described. The nonvolatile semiconductor memory device according to the second embodiment is identical to the first embodiment except points described below, and duplicated descriptions thereof will be omitted. FIG. 21 is a schematic cross-sectional view of the nonvolatile semiconductor memory device and shows a portion corresponding to FIG. 8 (a portion corresponding to the rectangle C in FIG. 6). Elements identical to those of the first embodiment are assigned with reference symbols identical to those assigned in the first embodiment.

In the nonvolatile semiconductor memory device according to this embodiment, as shown in FIG. 21, the protective layer 151 using silicon oxide (SiO₂) and shown in FIG. 8 is not disposed. Therefore, the second block insulating layer 150 including zirconium oxide (ZrO₂) and covering the memory columnar body 105 is directly exposed to the hot phosphoric acid in the process of removing the sacrifice layers of the step S105.

Hence, as shown in FIG. 20, the thicknesses D1 of the second block insulating layers 150 of the memory columnar bodies 105 positioned at the line L1 and the line L4 are slightly thinner than the thicknesses D2 of the second block insulating layers 150 of the memory columnar bodies 105 positioned at the line L2 and the line L3.

However, even when the protective layer 151 including silicon oxide (SiO₂) is not used, non-uniformity of the thicknesses of the second block insulating layers 150 including zirconium oxide (ZrO₂) is extremely slight. The reason is, as described above, etching rate of the zirconium oxide (ZrO₂) using the hot phosphoric acid is low, that is, about 1/60, compared with alumina (Al₂O₃). Therefore, regarding an effect given to the nonvolatile semiconductor memory device, difference in the thickness of the second block insulating layer 150 including zirconium oxide (ZrO₂) depending on their positions may be ignored.

Since the nonvolatile semiconductor memory device according to this embodiment does not use the protective layer 151 including silicon oxide (SiO₂), the manufacturing process is simplified.

### [Method of Manufacturing]

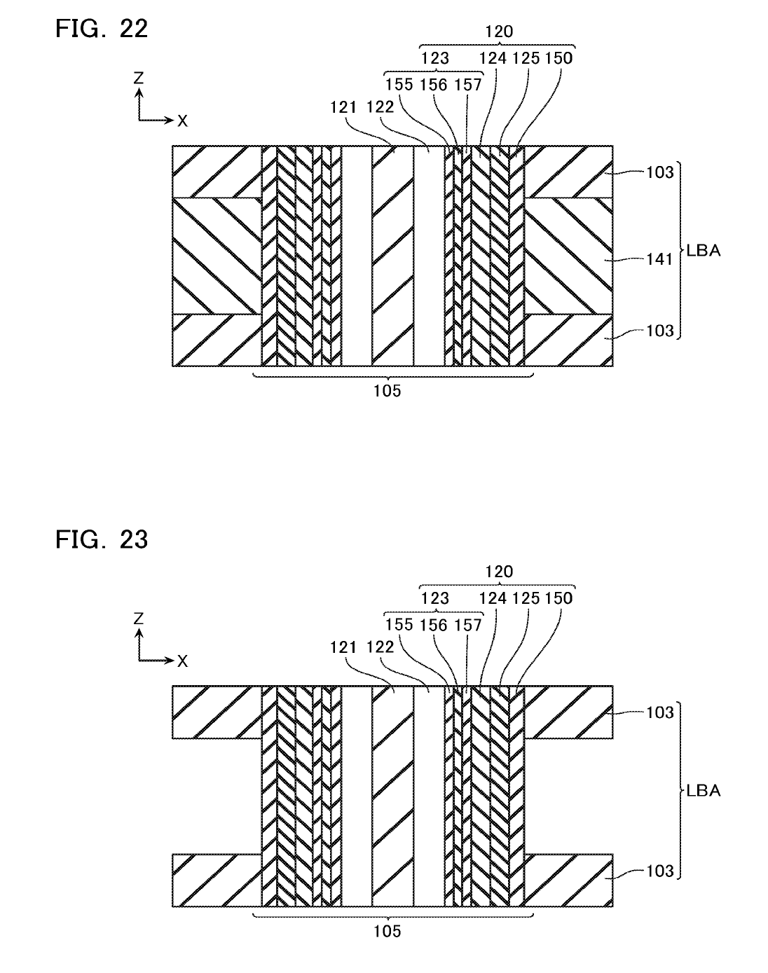

A method of manufacturing the nonvolatile semiconductor memory device according to the second embodiment will be described. Manufacturing processes identical to the first embodiment are performed until forming the openings op1 (step S102) shown in FIG. 11. As shown in FIG. 22, in the step S103, when forming each layer that configures the memory columnar body 105 on the side surface of the opening op1 by a method such as CVD, the protective layer 151 of silicon oxide (SiO₂) is not formed. In this embodiment, the second block insulating layer 150 including zirconium oxide (ZrO₂) is formed at first. Other steps are identical to the first embodiment.

Next, the sacrifice layers 141 are etched using the hot phosphoric acid to obtain a structure shown in FIG. 23. In the second embodiment, because there is no protective layer 151 of silicon oxide (SiO₂), the second block insulating layer 150 including zirconium oxide (ZrO₂) has slight non-uniformity of the thickness caused by non-uniformity of etching time depending on places.

Because the protective layer 151 including silicon oxide (SiO₂) does not exist, the next step S107 is performed without performing the step S106, and the barrier metal layer 133 is formed. All of the steps after the S107 are identical to the first embodiment; duplicated descriptions thereof will be omitted.

### Third Embodiment

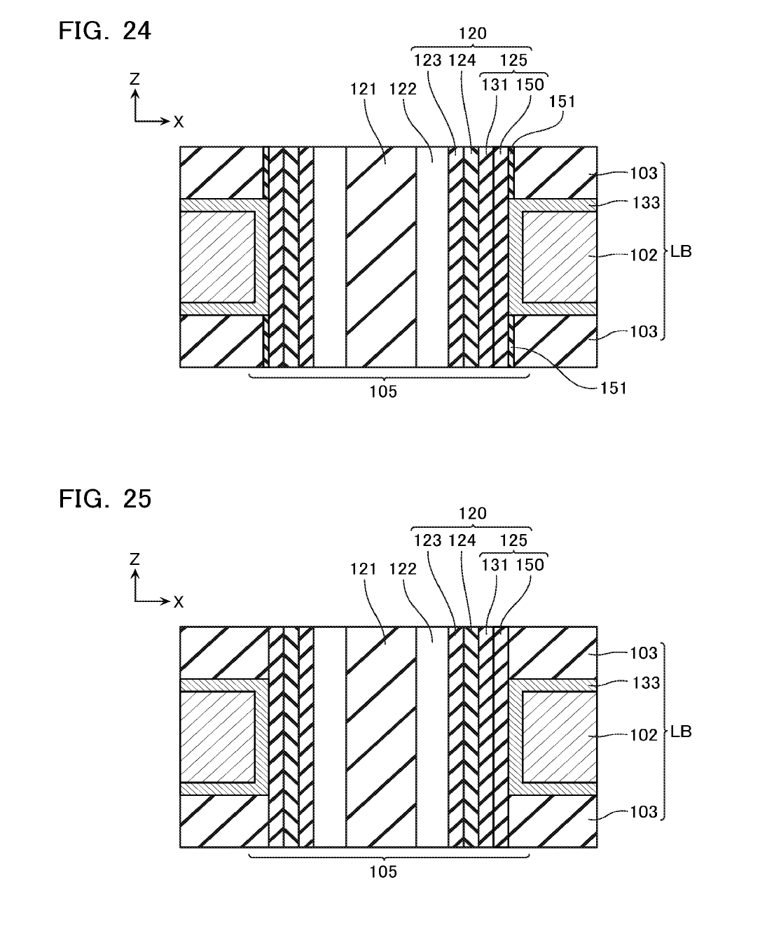

A nonvolatile semiconductor memory device according to a third embodiment is identical to the first embodiment except a configuration described below, and duplicated descriptions thereof will be omitted. FIG. 24 is a cross-sectional view showing part of the nonvolatile semiconductor memory device according to the third embodiment and showing the portion corresponding to FIG. 8 according to the first embodiment. Elements identical to those of the first embodiment are assigned with reference symbols identical to those assigned in the first embodiment in FIG. 24. In the first embodiment, the tunnel insulating layer 123 is configured by three layers of the oxide layer 157 formed of silicon oxide (SiO₂), the nitride layer 156 formed by three layers of silicon nitride (Si₃N₄) and the oxide layer 155 formed of silicon oxide (SiO₂). In this embodiment, the tunnel insulating layer 123 is configured by one layer silicon oxide (SiO₂). Since configurations except this difference are identical to the first embodiment, the same effects as the first embodiment can be obtained.

### Fourth Embodiment

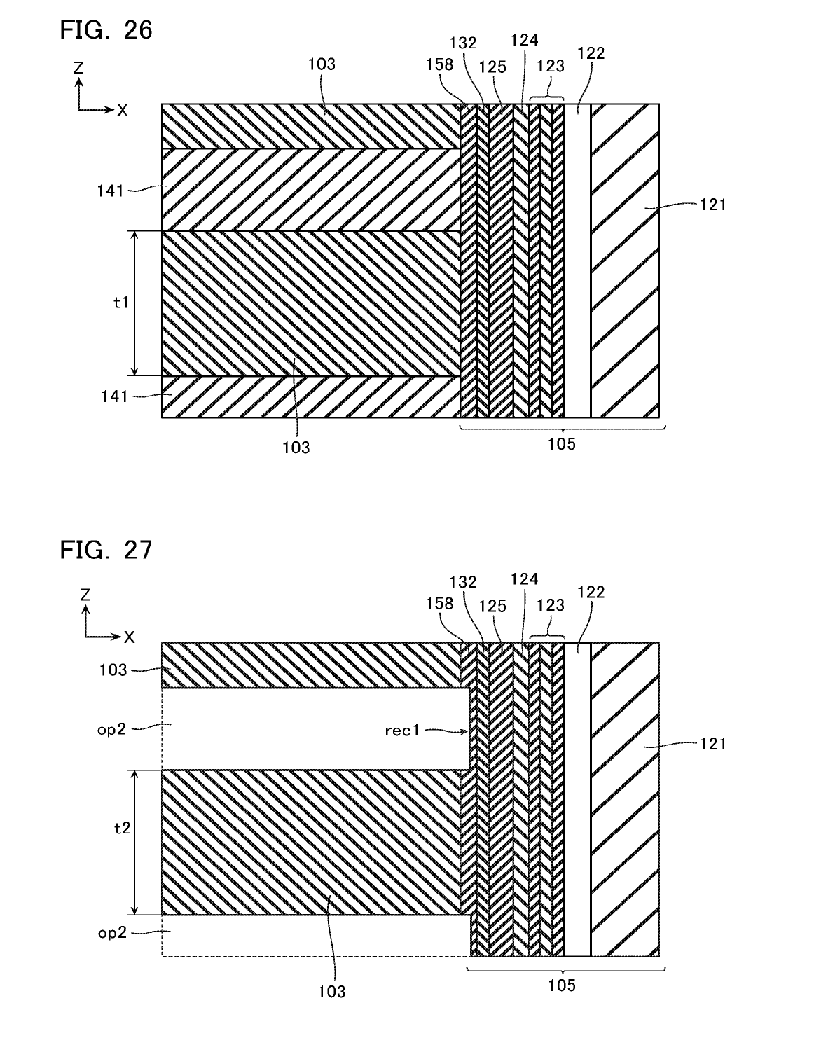

A nonvolatile semiconductor memory device according to a fourth embodiment is identical to the third embodiment except a point described below, and duplicated descriptions thereof will be omitted. FIG. 25 is a cross-sectional view showing part of the nonvolatile semiconductor memory device according to the fourth embodiment and showing a portion corresponding to FIG. 24 according to the third embodiment. Elements identical to those of the third embodiment are assigned with reference symbols identical to those assigned in the third embodiment in FIG. 25. This embodiment is different from the third embodiment in that the protective layer 151 including silicon oxide (SiO₂) and included in the third embodiment does not exist. This embodiment is identical to the third embodiment except this difference, and the same effects as the third embodiment can be obtained.

### COMPARATIVE EXAMPLE

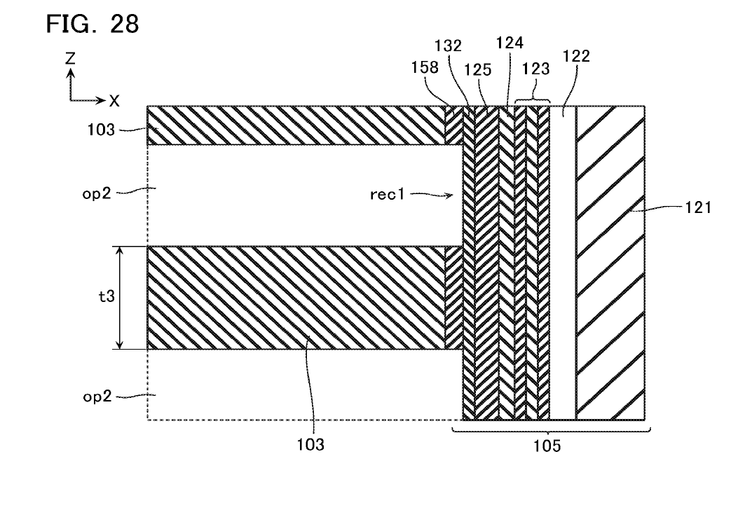

Next, a comparative example of the embodiments described above will be described, and efficiency of the embodiments described above will be described. In all of the first to fourth embodiments, the second block insulating layer 150 including zirconium oxide (ZrO₂) is disposed. In contrast, in the comparative example, the second block insulating layer 150 including zirconium oxide (ZrO₂) is not used. A method of manufacturing in this case will be described with reference to FIG. 26. FIG. 26 is a cross-sectional view corresponding to left half of FIG. 13 used for description about the method of manufacturing according to the first embodiment. FIG. 26 shows a state that the memory columnar body 105 is formed on a side surface of the opening op1 in FIG. 12.

In this comparative example, as shown in FIG. 26, the protective layer 151 including silicon oxide (SiO₂) and the second block insulating layer 150 including zirconium oxide (ZrO₂) used in the first embodiment are not included. Instead of this, this comparative example includes a second block insulating layer 132 configured by alumina (Al₂O₃). Protection of the second block insulating layer 132 configured by alumina (Al₂O₃) depends on only a protective layer 158 configured by one layer silicon oxide (SiO₂).

Next, as shown in FIG. 27, openings op2 are formed by etching of the sacrifice layers 141 using the hot phosphoric acid. In this step, the thickness of the interlayer insulating layer 103 that contacts the sacrifice layers 141 slightly decreases to a thickness t2 compared with a thickness t1 of the interlayer insulating layer 103 before etching. Moreover, a thickness of the protective layer 158 configured by silicon oxide (SiO₂) decreases. A decrement (depth) at this time is shown as recess rec1 in FIG. 27. It is necessary to form the protective layer 158 of silicon oxide (SiO₂) thicker enough than a depth of the recess rec1, because the hot phosphoric acid contacts the second block insulating layer 132 configured by alumina (AlO₂) and causes deterioration thereof when the thickness of the protective layer 158 configured by silicon oxide (SiO₂) decreases and becomes zero.

However, because the protective layer 158 of silicon oxide (SiO₂) that has low permittivity exists between the conductive layers 102 (not illustrated) embedded in the openings op2 at a former process and the first block insulating layer 125 that has high permittivity, performance of the memory cells MC decreases. Because of this, a process removing the remaining protective layer 158 of silicon oxide (SiO₂) by diluted fluoric acid that does not damage the second block insulating layer 132 configured by alumina (AlO₂) is necessary. The result of performing this process is shown in FIG. 26.

Because the interlayer insulating layers 103 configured by silicon oxide (SiO₂) are simultaneously etched when removing the protective layer 158 of silicon oxide (SiO₂) by diluted fluoric acid, the thicknesses of the interlayer insulating layers 103 further decrease and become a thickness t3. Accordingly, the thicknesses of the conductive layers 102 embedded in the openings op2 and the thicknesses of the interlayer insulating layers 103 are different from designed values; preferable performance of the nonvolatile semiconductor memory device may not be obtained.

### [Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed:

1. A semiconductor memory device, comprising:
a stacked body including a plurality of control gate electrodes stacked above a substrate;
a semiconductor layer extending in a first direction intersecting with the substrate and facing the plurality of control gate electrodes; and
a gate insulating layer disposed between the control gate electrodes and the semiconductor layer, wherein
the gate insulating layer includes zirconium oxide at a position facing the control gate electrodes.

2. The semiconductor memory device according to claim 1, further comprising:
an isolation insulating film disposed between a plurality of the stacked bodies and having longitudinally a second direction intersecting with the first direction, wherein
the semiconductor layer is arranged in a plurality of arrays in one of the plurality of the stacked bodies, and
a thickness of the zirconium oxide positioned at a first array in the plurality of arrays is thinner than a thickness of the zirconium oxide positioned at a second array in a position farther than the first array from the isolation insulating film.

3. The semiconductor memory device according to claim 1, further comprising:
a protective layer including silicon oxide and being arranged at a side closer to the control gate electrodes than the zirconium oxide.

4. The semiconductor memory device according to claim 3, wherein
the protective layer is disposed between an interlayer insulating layer and the zirconium oxide, the interlayer insulating layer electrically separating the plurality of control gate electrodes, and is not disposed between the zirconium oxide and the plurality of control gate electrodes.

5. The semiconductor memory device according to claim 1, wherein
the gate insulating layer includes a tunnel insulating layer, a charge accumulation layer and a block insulating layer.

6. The semiconductor memory device according to claim 5, wherein
the tunnel insulating layer is an insulating layer including silicon oxide.

7. The semiconductor memory device according to claim 5, wherein
the tunnel insulating layer is configured by two first insulating layers including silicon oxide, and a second insulating layer including silicon nitride and disposed between the two first insulating layers.

8. The semiconductor memory device according to claim 5, wherein
the block insulating layer has an insulating layer including silicon oxide.

9. The semiconductor memory device according to claim 5, wherein
the charge accumulation layer is a layer including silicon nitride.

10. The semiconductor memory device according to claim 1, wherein
the control gate electrodes face the zirconium oxide via a barrier metal layer.

11. A method of manufacturing a semiconductor memory device, comprising:
stacking a plurality of interlayer insulating layers and sacrifice layers above a substrate to form a stacked body;
forming in the stacked body a first opening in a first direction intersecting with the substrate;
forming a protective layer including silicon oxide, a gate insulating layer including a block insulating layer that includes zirconium oxide, and a semiconductor layer in this order on a side surface of the first opening to embed the first opening;
forming a second opening in the first direction in the stacked body;
removing the sacrifice layers via the second opening; and
embedding conductive layers in regions formed by removing the sacrifice layers.

12. The method of manufacturing a semiconductor memory device according to claim 11, wherein
the conductive layers are embedded via barrier metal layers in the regions formed by removing the sacrifice layers.

13. The method of manufacturing a semiconductor memory device according to claim 11, wherein
the sacrifice layers are removed via the second opening using a first solution, and
the protective layer is removed using a second solution.

14. The method of manufacturing a semiconductor memory device according to claim 11, wherein
the first solution is hot phosphoric acid, and
the second solution is diluted hydrofluoric acid.
